(19) United States
(12) Patent Application Publication
(10) Pub. No.: US 2023/0095749 A1
(43) Pub. Date: Mar. 30, 2023

(54) SOLDER MATERIAL, LAYER STRUCTURE, CHIP PACKAGE, METHOD OF FORMING A LAYER STRUCTURE, AND METHOD OF FORMING A CHIP PACKAGE

(71) Applicant: Infineon Technologies AG, Neubiberg (DE)

(72) Inventors: Alexander Heinrich, Bad Abbach (DE); Alexander Roth, Zeitlarn (DE); Catharina Wille, Regensburg (DE)

(21) Appl. No.: 17/947,353

(22) Filed: Sep. 19, 2022

(30) Foreign Application Priority Data
Sep. 27, 2021 (DE) 102021124877.9

(51) Int. Cl. H01L 23/00; B23K 35/02; B23K 35/26

(52) U.S. Cl. CPC H01L 24/29; H01L 24/32; H01L 24/83; B23K 35/0244; B23K 35/262; H01L 2924/3656; H01L 2924/3651; H01L 2224/32245; H01L 2224/32225; H01L 2224/8381; H01L 2224/32503; H01L 2224/83359; H01L 2224/83379; B23K 2101/40

(57) ABSTRACT

A solder material is provided. The solder material may include a first amount of particles having particle sizes forming a first size distribution, a second amount of particles having particle sizes forming a second size distribution, the particle sizes of the second size distribution being larger than the particle sizes of the first size distribution, and a solder base material in which the first amount of particles and the second amount of particles is distributed. The first amount of particles and the second amount of particles consist of or essentially consist of a metal of a first group of metals. The first group of metals includes copper, silver, gold, palladium, platinum, iron, cobalt, and aluminum. The solder base material includes a metal of a second group of metals. The second group of metals includes tin, indium, zinc, gallium, germanium, antimony, and bismuth.

### TECHNICAL FIELD

Various embodiments relate generally to a solder material, to a layer structure, to a chip package, to a method of forming a layer structure, and to a method of forming a chip package.

### BACKGROUND

For power applications, dies and clips are today soldered with a high lead (Pb) based soft solder paste. Since, however, an EU-wide ban of lead is under way (see, e.g., RoHS, ELV rules), an alternative die- and clip-attach system may need to be developed to be as least as good as the paste system based on a high lead content.

At present, there is no general replacement available for a solder that has a high lead content. Potential alternative solutions are only designed to address single applications. They are unsuitable for a general-purpose use.

For example, AuSn may not generally be used as a replacement for Pb-soldering due to significantly higher costs and tighter design rules/geometric restrictions.

Thin dies may be a challenge for a couple of potential solutions, especially for those without melting materials. Other potential alternative solutions may have too low a melting point, which may be an issue during second level soldering (for this, a minimum melting temperature of 270° C. may be required).

Adhesives with a filling with a high silver content as a potential solution may show worse thermal and electrical performance compared to the solder with the high lead content.

Other high performance solutions may not be cost competitive.

### SUMMARY

A solder material is provided. The solder material may include a first amount of particles having particle sizes forming a first size distribution, a second amount of particles having particle sizes forming a second size distribution, wherein the particle sizes of the second size distribution are larger than the particle sizes of the first size distribution, and a solder base material in which the first amount of particles and the second amount of particles is distributed, wherein the first amount of particles and the second amount of particles consists of or essentially consists of a metal of a first group of metals, the first group including copper, silver, gold, palladium, platinum, iron, cobalt, and aluminum, and wherein the solder base material includes a metal of a second group of metals, the second group including tin, indium, zinc, gallium, germanium, antimony, and bismuth.

A solder material is provided. The solder material may include a first amount of particles having particle sizes forming a first size distribution, a second amount of particles having particle sizes forming a second size distribution that is separated from the first size distribution, wherein the particle sizes of the second size distribution are larger than the particle sizes of the first size distribution, and a solder base material in which the first amount of particles and the second amount of particles is distributed, wherein the first amount of particles and the second amount of particles consists of or essentially consists of a metal of a first group of metals, the first group including nickel, copper, silver, gold, palladium, platinum, iron, cobalt, and aluminum, and wherein the solder base material includes a metal of a second group of metals, the second group including indium, zinc, gallium, germanium, antimony, and bismuth.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

each of FIG. 1A to FIG. 1C shows an illustration if a solder material in accordance with various embodiments;

each of FIG. 2A to FIG. 2I shows a schematic cross-sectional view of a layer structure in accordance with various embodiments;

each of FIG. 3A and FIG. 3B shows a schematic cross-sectional view of a layer structure in accordance with various embodiments;

FIG. 4 shows a schematic cross-sectional view of a chip package in accordance with various embodiments;

each of FIG. 5A and FIG. 5B shows particle distributions of a first amount of particles and of a second amount of particles in a solder material in accordance with various embodiments;

FIG. 6 shows a flow diagram of a method of forming a layer structure in accordance with various embodiments; and

FIG. 7 shows a flow diagram of a method of forming a chip package in accordance with various embodiments.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, a solder material is provided that may be used as a drop-in replacement for solder paste systems having a high lead content (also referred to as “high-lead solders”).

In various embodiments, a solder material is provided that may be used as an alternative to a solder material having nickel particles distributed in a tin-based solder. In other words, a solder material based on a similar or the same principle as the solder material having the nickel particles in the tin-based solder is provided, but with material combinations that are different from nickel/tin. A group of possible metals is provided that may be used for the particles (which may include nickel, in which case the solder base material may not include the tin), and another group of possible metals is provided that may form at least part of the solder base (which may include tin, in which case the particles may not include the nickel).

In various embodiments, the solder material that is an alternative to the nickel-tin-solder may be provided to address specific requirements that cannot be fulfilled by the combination of Ni and Sn.

For example, a melting temperature of the solder material may be adjusted to specific requirements. The melting temperature of the initially proposed Sn solder cannot be modified significantly.

In order to change the melting temperature of the paste, the melting fraction may for example be changed from Sn to In (or an InSn-alloy) for a lower melting temperature (which may, after cooling, lead to reduced stress in a chip package in which the solder material may be included) or to Zn (or a ZnSn-alloy) for a higher melting temperature (and an increased stress in a chip package in which the solder material may be included).

For example, a melting temperature of the resulting intermetallic phase (IMC) may be engineered by the application of different materials for the particles and the solder base: The Ni₃Sn₄ IMC may melt at 795° C. If a lower melting temperature is desired, the Ni may for example be exchanged by Cu (which may lead to an intermetallic compound of Cu6Sn with a melting temperature of Tₘₑₗₜ=412° C.) or Au (Tₘₑₗt AuSn=280° C.) or the solder material may for example be exchanged e.g. by In to lower the melting temperature (Tmelt In₇Ni₃=403° C.), or by Zn to raise the melting temperature (Tmelt NiZn=867° C.).

In various embodiments, a thermal and electrical conductivity of the IMC may be engineered, in that the conductivity of the solder interconnect may be adjusted by the selection of the solder and particle material. The initially proposed NiSn-system has a thermal conductivity of 19 W/mK. In an exemplary embodiment, an exchange of the Ni by Cu may almost double thermal conductivity to 34 W/mK, or the thermal conductivity may for example be tripled by an exchange of the Ni to Au (58 W/mK)

In various embodiments, a stress (after cooling) in a chip package that includes the solder material may be addressed by suitable changes in the composition as described above. The stress will largely depend on the soldering temperature, the solidification temperature of the solder and the mechanical properties of the resulting IMC.

In various embodiments, an adaption to metallization requirements may be taken care of by a suitable selection of the material combination of the solder material. In the nickel-tin solder, a final metallization provided on metal surfaces to be joined by the solder material may (the bonding surfaces) often not be chosen freely, which may in particular be problematic in a case where the metal surfaces are provided by third parties. In such a case, an adaption of the solder base material and/or of the particles may influence (e.g. reduce) a consumption of a material (metal) on the bonding surfaces (BSM).

In various embodiments, the solder material may include a bimodal distribution of particles. The bimodal distribution may include a first amount of particles having a relatively small size, e.g. in a range from about 1 μm to about 20 μm, and a second amount of particles having a larger size, e.g. in a range from about 30 μm to about 50 μm. The particles having the relatively small size may also be referred to as the small-sized particles or as the small particles, and the particles having the relatively large size may also be referred to as the large particles, the large-sized particles or the big particles. The small particles and the large particles may be distributed in a solder base material.

In various embodiments, the first amount of particles and the second amount of particles consist of or essentially consist of a metal (also referred to as particle metal) of a first group of metals, the first group including copper, silver, gold, palladium, platinum, iron, cobalt, and aluminum, and wherein the solder base material includes a metal (also referred to as solder base metal) of a second group of metals, the second group including tin, indium, zinc, gallium, germanium, antimony, and bismuth. In other words, in these embodiments, the particles may include or consist of a material that is different from nickel, and the solder base material may include tin or a metal that is different from tin.

Preferable material combinations and intermetallic phases that may be formed from these material combinations are described below.

In various embodiments, the first amount of particles and the second amount of particles consist of or essentially consist of a metal (also referred to as particle metal) of a first group of metals, the first group including nickel, copper, silver, gold, palladium, platinum, iron, cobalt, and aluminum, and wherein the solder base material includes a metal (also referred to as solder base metal) of a second group of metals, the second group including indium, zinc, gallium, germanium, antimony, and bismuth. In other words, in these embodiments, the particles may include or consist of a material that includes nickel or that is different from nickel, and the solder base material may include a metal that is different from tin.

Preferable material combinations and intermetallic phases that may be formed from these material combinations are described below.

During the soldering, the small particles may be completely alloyed with the solder base material surrounding them, e.g. a soft solder including a metal as described above, without being directly converted to the high-melting intermetallic phase (IMC). Only after a further reaction with metal from the larger particles (and, optionally, with interfaces to the metal surfaces to be joined), the majority of the interconnect material may be converted to high-melting-point IMC.

A main constituent (e.g., between 70at % and 95at %, e.g. >80at %) of the layer formed by the solder material after a hardening may be an intermetallic phase, or a mixture of two or more phases, depending on the specific process flow.

Intermetallic phases that may form, depending on the material selection for the particles and the solder base, respectively, may include or consist of any of the following: an indium-copper intermetallic phase, for example Cu₁₁In₉ and/or Cu₂In, an indium-nickel intermetallic phase, for example In₇Ni₃ and/or In₃Ni₂, an indium-silver intermetallic phase, for example Ag₃In₂, and/or Ag₃In, and/or Ag₂In, an indium-gold intermetallic phase, for example AuIn, and/or Au₇In₃ and/or AuIn₂, an indium-palladium intermetallic phase, for example In₂Pd₅, and/or In₂Pd₄, and/or In₂Pd₆, an indium-platinum intermetallic phase, for example Pt₃In, a zinc-nickel intermetallic phase, for example NiZn-beta and/or NiZn-gamma, a zinc-silver intermetallic phase, for example AgZn-gamma and/or Ag₃Zn, a zinc-gold intermetallic phase, for example Au₃Zn, and/or Au₆Zn₃, and/or Au₄Zn₅, a zinc-palladium intermetallic phase, for example Pd₂Zn and/or PdZn₂, a zinc-platinum intermetallic phase, for example Pt₃Zn and/or PtZn, an antimony-copper intermetallic phase, for example Cu₂Sb, an antimony-silver intermetallic phase, for example SbAg₃, an antimony-gold intermetallic phase, for example AuSb₂, an antimony-palladium intermetallic phase, for example Pd₃Sb, an antimony-platinum intermetallic phase, for example Pt₅Sb, a bismuth-nickel intermetallic phase, for example BiNi and/or Bi₃Ni, a bismuth-gold intermetallic phase, for example Au₂Bi, a bismuth-palladium intermetallic phase, for example BiPd, and/or Bi₃Pd₅, and/or BiPd₃, and a bismuth-platinum intermetallic phase, for example BiPt and/or Bi₂Pt, an indium-nickel intermetallic phase, for example In₇Ni₃ and/or In₃Ni₂, a zinc-nickel intermetallic phase, for example NiZn-beta and/or NiZn-gamma, and a bismuth-nickel intermetallic phase, for example BiNi and/or Bi₃Ni.

The bimodal distribution of particles in the solder material may allow the small particles to melt first during the soldering process, and to distribute evenly within the liquefied solder material and in contact with metal surfaces to be connected, and to reach a high content of the (metal) particle material in the liquefied solder material that may be required for the forming of the intermetallic phase (and thus the hardening of the solder material) only after a fraction of the metal included in the large particles has melted.

In various embodiments, the solder material and a connection formed using the solder material may fulfill the above requested requirements, e.g. regarding versatility, consts, etc. In particular, a melting temperature of the resulting interconnect may be above 270° C., such that the interconnect may be able to withstand second level soldering.

In various embodiments, the solder material may be used for mounting a die, for example for mounting the die to a conductive substrate, for example to a leadframe.

In various embodiments, the solder material may be used for attaching an electrically conductive structure to a die, for example for attaching a clip to the die.

In various embodiments, a layer structure may be formed by mounting a chip to a metal layer using the solder material. The metal layer may have a top layer (optionally with a thin (e.g., a few nanometers thick) protective layer). A chip contact surface may have a top layer (optionally with a thin (e.g., a few nanometers thick) protective layer) including a metal.

As another way to phrase it, in a layer structure, a chip may be mounted to a conductive substrate and/or may be connected to a conductive structure using the solder material in accordance with various embodiments.

In various embodiments, a dedicated metallization may be provided on chip contact surfaces to be soldered and/or on the conductive substrate and/or the conductive structure, respectively. The chip contact surfaces may, for example, include or consist of one or more layers on the die front- and/or backside. The metallization on the conductive substrate may for example be one or more layers on a leadframe or the like. The metallization on the conductive structure may for example be one or more layers on a clip, a spacer, a substrate as used for direct copper bonding, or the like.

The interconnect may in various embodiments be formed using one or more layers in combination with a paste that has a solder base including a first metal, and a high metal content of a second metal (between, for example, 35at % and 90at %), wherein the two metals may be selected suitably for forming an intermetallic phase during the soldering process. This may allow to reach (after solidification of the solder) a melting temperature Tmelt>270° C.

The dedicated metallization (e.g., plating) of the bonding surfaces may in various embodiments be configured to avoid a strong intermetallic growth and Kirkendall voiding between a metal of the conductive substrate or the conductive structure, respectively, which may for example include or consist of copper (Cu) as one of the connection partners and tin (Sn) as the other of the connection partners. The plating may include a nickel layer that may act as a diffusion barrier (against a mixing of copper and tin) and as an alloying element.

In various embodiments, a composition of the solder material and of the metal layers forming part of the interconnect may be configured in such a way that, after the solder process, no pure solder base metal may remain in a fillet area. Configurations that may be suitable for achieving this may include the herein described amounts of the metal included in the (small and large) particles and/or metal that is provided as part of the solder base material.

In various embodiments, by forming an interconnect using the solder material as described above, the interconnect layer as a whole may be close to thermodynamic equilibrium. As a result of this, further alloying during a subsequent heat treatment (e.g. during reliability testing or in the application) may be reduced, and a mechanical stability may be increased. This may result in a higher flexibility regarding an overall design, because thicknesses of platings and chip metallizations, e.g. chip contact surfaces, may be reduced.

By suitable plating, for example nickel plating, all surfaces that are in contact with the solder material, a Kirkendall voiding at a reaction front (e.g., of a copper surface, e.g. Sn—Cu) may be avoided. Furthermore, a volume shrink due to ongoing phase formation may be avoided. Thus, reliability of the solder joint may be increased.

The proposed lead free system may in various embodiments include a conductive Cu based element (some dopings might be included) having a thickness from about 100 μm to about 5 mm. The conductive element may be partly or fully plated with a layer having a thickness in the range from about 100 nm to about 5 μm. The lead-free system may further include a (soft) solder base including at least one of the metals described above as possible metals for the solder base. The metal portion of the solder included in the (e.g., small and large) particles may be in a range from about 35at % to about 90at %.

Using the solder material in accordance with various embodiments for attaching a chip to a substrate, an increased stability of the so-called die attach may be achieved, due to the high-temperature intermetallic phases.

Each of FIG. 1A to FIG. 1C shows an illustration if a solder material 100 in accordance with various embodiments, and each of FIG. 5A and FIG. 5B shows particle distributions of a first amount of particles and of a second amount of particles in a solder material in accordance with various embodiments.

The solder material 100 may include particles consisting of or essentially consisting of a particle metal, and a solder base including a solder base metal.

The particle metal may include, e.g. be provided as, a first amount of particles 104_1 and a second amount of particles 104_2.

A sum of the first amount of particles 104_1 and the second amount of particles 104_2 may be a total amount of the particle metal or less, wherein the first amount of particles 104_1 may be between 5 at % and 60 at % of the total amount of the particle metal, for example between 25 at % and 60 at %, and wherein the second amount of particles 104_2 may be between 10 at % and 95 at %, for example between 10 at % and 75 at %, of the total amount of the particle metal.

The first amount of particles 104_1 may have particle sizes forming a first size distribution, and the second amount of particles 104_2 may have particle sizes forming a second size distribution. FIGS. 5A and 5B, respectively, show exemplary size distributions. that is separated from the first size distribution, wherein the particle sizes of the second size distribution are larger than the particle sizes of the first size distribution. In other words, a size of each particle of the second particle distribution may be larger than a size of each particle of the first particle distribution. The first size distribution and the second size distribution may together form a bimodal particle size distribution, with no overlap (or essentially no overlap) between the size distributions. FIG. 5A shows such an exemplary size distribution.

As another way to describe this, each of the first size distribution and the second size distribution may have a full width and a median size. A difference between the median size of the large particles 104_2 and the median size of the small particles 104_1 may be larger than half of a sum of the full width of the first size distribution and the full width of the second size distribution. In various embodiments, a largest particle of the first size distribution may be smaller than the smallest particle of the second size distribution.

The terms particle size or particle size distribution may refer to a measured size or measured distribution, even though the measurement may not necessarily be performed on the particles themselves, but rather on representative particles or particle distributions that may be expected to return size values that apply also to the particles of the various embodiments, for example representative particles obtained by the same production process as the particles of various embodiments.

The measurement may be carried out with an appropriate method, e.g. an aerodynamic particle size spectrometer.

In various embodiments, the upper and lower particle size limits provided herein may be understood to be sizes measured with such an appropriate method.

The particle size distribution of the particles, e.g. of the small particles 104_1 and/or of the large particles 104_2, which may form a technical material, may include or consist vastly of the particles with the specified (measured) size or size range. However, in various embodiments, the distribution of particles (e.g., of the small particles 104_1 and/or of the large particles 104_2) may include a small fraction (e.g., a single digit percentage of the total amount of the particles in the distribution) that may exceed or fall below the given size or size range.

This means that two (technical) particle distributions having well-separated median particle sizes, e.g. median particle sizes that may differ from each other by a factor of two or even by an order of magnitude, may have overlapping particle sizes affecting up to, for example, a single digit percentage of the particles.

As described above, the bimodal distribution of particles in the solder material may be formed with different functions of the small particles 104_1 and the large particles 104_2 in mind, in that the small particles 104_1 are configured to melt first during the soldering process, and to form an evenly distributed liquid alloy as a prerequisite for the forming of the intermetallic phase. The large particles 104_2 are configured to provide further melted particle metal for the forming of the intermetallic phase (and thus the hardening of the solder material) during a later stage.

Specific shapes of the size distributions (e.g. peaked like in FIG. 5A and the distribution of the small particles 104_1 of FIG. 5B, e.g., Gaussian, lopsided like the distribution of the large particles in FIG. 5B, or a more or less even distribution) and characteristic sizes (absolute and/or relative) of the small particles 104_1 and the large particles 104_2, e.g., an arithmetic average or a median of the size of the respective distribution, and a relation (e.g., in weight or atomic percentage) of the first amount of particles 104_1 and the second amount of particles 104_2 may be adjusted in accordance with the materials involved. In FIG. 1A to 1C, the characteristic sizes are indicated as D1 for the small particles, D2 for the large particles, and (in FIG. 1B) D3 for a third amount of intermediate-size particles.

In various embodiments, a shape of the size distributions may be determined by a production process of the particles, and absolute and relative particle sizes of the first size distribution and of the second size distribution, respectively, may be adjusted in consideration of the respective shapes of the distributions.

For example, an arithmetic average, a median, or any other type of suitable average of the size of the second amount of particles may be at least about twice as large as the corresponding size of the first amount of particles. Exemplary values for the particle sizes of the particles of the first amount of particles 104_1 and of the particles of the second amount of particles 104_2, respectively, are provided below.

If the solder material 100 additionally includes metal particles outside the desired size ranges corresponding to the first size distribution and the second size distribution (and, optionally, further specific desired size distributions), their amount may be sufficiently low to ensure that the desired soldering behaviour (as described above) is not compromised.

The particles of the first amount of particles 104_1 may have a size in a range from about 1 μm to about 20 μm, e.g. between about 3 μm and 7 μm or between about 5 μm and 15 μm. The particles of the second amount of particles 104_2 may have a size in a range from about 30 μm to about 50 μm, for example between about 35 μm and about 40 μm.

The lower limit of the size of the first amount of particles 104_1 may be set to be about 1 μm. Thereby, it may be ensured that the first amount of particles 104_1 may not be affected by restrictive legislation regarding nanoparticles. Furthermore, the size of 1 μm or more may mean that an effect of an oxidation of the small particles may be limited to a tolerable level.

The lower limit of the size of the second amount of particles 104_2 may be set to be about 30 μm. This may ensure that, depending on what is desired, a core of the large particles 104_2 may remain as cores of pure particle metal after the soldering, or that the second amount of particles 104_2 has a size that is also dissolved. A maximum size of the second amount of particles 104_1 may be determined by a thickness of bond lines to be arranged between two metal surfaces to be connected by the solder material 100, wherein the bond lines may set the separation between the two metal surfaces. The maximum size of each of the second amount of particles 104_2 may be smaller than about half the thickness of the normal bond lines (which may be about 80 μm to 100 μm, such that the maximum size of the second amount of particles 104_2 may be between about 40 μm and about 50 μm.

Each of FIG. 5A and FIG. 5B shows particle distributions of a combination of a first amount of particles 104_1 and of a second amount of particles 104_2 in a solder material 100 in accordance with various embodiments.

In various embodiments, all the particle metal in the solder material 100 may be contributed by the first amount of particles 104_1 and by the second amount of particles 104 2. Such an embodiment is shown in FIG. 5A. An absolute or relative amount of at % contributed by the first amount of particles 104_1 and by the second amount of particles 104_2, respectively, may be difficult to estimate from this qualitative visualization, because a volume (and hence a number of atoms) of each of the larger particles 104_2 is much bigger than a volume (and hence a number of atoms) of each of the smaller particles 104_1.

In various embodiments, only a fraction of the particle metal in the solder material 100 may be contributed by the first amount of particles 104_1 and by the second amount of particles 104_2. In various embodiments, the solder material 100 may include further particles 550 in addition to the first amount of particles 104_1 and the second amount of particles 104_2. Such an embodiment is shown in FIG. 1C and in FIG. 5B.

The first amount of particles 104_1 may have sizes between about 5 μm and about 15 μm. The second amount of particles 104_2 may have sizes between about 30 μm and about 50 μm. The size distribution of the second amount of particles 104_2 may be part of a larger size distribution ranging from the minimum size for the first amount of particles 104_1 to the maximum size of the second amount of particles 104_2, and which may include, apart from the second amount of particles 104_2 and some of the first amount of particles 104_1, a further amount of particles 104_E (see FIG. 1C). The broad particle size distribution of the large particles 104_2 may for example be obtained by precipitation or the like with subsequent sifting.

In various embodiments, the particle metal may further include a third amount of particles 104_3, wherein a sum of the first amount of particles 104_1, the second amount of particles 104_2, and the third amount of particles 104_3 is the total amount of the particle metal or less. The third amount of particles 104_3 may contribute between 10 at % and 85 at % (for example between 10 at % and 65 at %) of the total amount of the particle metal. The particles of the third amount of particles 104_3 may have a size in a range from more than about 20 μm to less than about 30 μm. A corresponding embodiment is shown in FIG. 1B. The particles 104_1, 104_2, 104_3 in the solder material 100 may thus have a trimodal distribution, which may allow to fine-tune a formation of the intermetallic phase even better.

In various embodiments, the particles may be spherical or essentially spherical, for example as opposed to a spattered particle shape. For example, the particles may have an outer surface with only convex portions, i.e. without concave portions on the surface. In FIG. 1A to 1C, most of the particles 104_1, 104_2, 104_3 are represented by circles indicating spherical particles. However, the two particles indicated by arrows are illustrated as ellipses indicating ellipsoid particles.

The size of each of the particles 104_1, 104_2, 104_3 may be understood to be an average of its size along its longest axis and a size along its shortest axis (which in case of the spherical particle are identical).

In various embodiments, a particle metal amount of the solder material 100 may be in a range from about 35 at % to about 90 at %. A remaining portion of the solder material 100, i.e. between about 10 at % and about 65 at % of the solder material 100, may partially or completely be formed by the solder base metal. Besides a dominant solder base metal, further materials may be part of the solder, for example with a lower amount than the solder base metal, e.g. silver (Ag), gold (Au), platinum (Pt), and/or palladium (Pd).

The solder material 100 may in various embodiments be configured as a solder paste, for example as a soft solder including the solder base metal, in which the first amount of particles 104_1 and the second amount of particles 104_2 (and, optionally, the third amount of particles 104_3 and/or the further particles 104_E) are distributed.

In various embodiments, the solder material 100 may be configured as a solder wire including the solder base metal and the particles 104_1, 104_2 (and, optionally, the third amount of particles 104_3 and/or the further particles 104_E), or as a different kind of preformed solid solder material, e.g. a solder sheet (which may optionally be pre-shaped to fit a foreseen application). The preformed solder material may for example be formed as a compacted solder powder or as a solder preform.

A behavior during the soldering process for which the solder material 100 is configured will be described in context with a layer structure 200 in accordance with various embodiments, for example as shown in FIG. 2A to FIG. 2I, in FIG. 3A or FIG. 3B.

Each of FIG. 2A to FIG. 21, FIG. 3A and FIG. 3B shows a schematic cross-sectional view of a layer structure 200 in accordance with various embodiments.

In the exemplary embodiments of FIG. 2A to FIG. 2H, FIG. 3A and FIG. 3B, the layer structure 200 includes a chip 220 (also referred to as die). The chip 220 may for example be a semiconductor chip, e.g., based on silicon (Si), silicon carbide (SiC), gallium nitride (GaN), or other semiconductor materials as known in the art. A thickness of the chip 220 may be in a range from about 20 μm to about 380 μm, wherein the thickness may include the chip metallizations 220B, 220F.

Various embodiments may not include a chip 220, as shown in the exemplary embodiment of FIG. 2I.

The layer structure 200 may include a first layer 222 including a metal, for example nickel or a nickel alloy or a different metal, for example the particle metal, and a third layer 222 including a metal, for example nickel or a nickel alloy or a different metal, for example the particle metal, and a second layer 101 between the first layer 222 and the third layer 222.

The first layer 222 and the third layer 222 may be similar or identical or may be configured differently. Since they are, however, in principle interchangeable, they are identified by the same reference sign 222.

Table 1 shows what kind of metals may be suitable for the particles, for the metallization (e.g., as the as the first layer 222 and/or as the second layer 222, respectively, referred to in table 1 as “substrate”) (the respective metals are arranged along the top row, their suitability as particles indicated in the second row, and their suitability as the metallization in the third row), and for the solder base metal (the respective metals are arranged along the leftmost column) and, in particular, if the combination of particle/substrate metal and solder base material is feasible:

TABLE 1

| | Cu | Ni | Ag | Au | Pd | Pt | Fe | Co | Al | Mo | Mn |
|---|---|---|---|---|---|---|---|---|---|---|---|
| Particle | X | + | + | (+) | (+) | (+) | (+) | (+) | (+) | Only in | (+) |
| Substrate | + | + | + | (+) | (+) | (+) | (+) | (+) | (+) | mixture | (+) |
| Sn | + | + | + | (+) | (+) | (+) | (+) | (+) | (+) | | (+) |
| In | + | + | + | (+) | (+) | (+) | X | (+) | (+) | | X |
| Zn | X | + | + | (+) | (+) | (+) | (+) | (+) | (+) | | (+) |
| Ga | + | + | + | (+) | (+) | (+) | X | (+) | (+) | | X |
| Ge | + | + | + | (+) | (+) | (+) | X | (+) | (+) | | X |
| Sb | + | + | + | (+) | (+) | (+) | (+) | (+) | (+) | | X |
| Bi | + | + | + | (+) | (+) | (+) | X | (+) | X | | X |

In table 1, “+” may indicate a metal or metal combination that was tested to be successful, (+) indicates a metal or metal combination that is assumed to be successful, but is not tested yet, and X may indicate a metal or metal combination that is not suitable for the respective application/combination.

The second layer 101 may be formed from the solder material 100. To differentiate between the solder material 100 before the soldering process and the solder layer 101 formed by the soldering process, different reference signs 100, 101 are used. The first layer 222 and/or the third layer 222 may include, consists of, or essentially consists of at least one of a group including nickel, nickel vanadium (NiV), a nickel phosphide, e.g. NiP, and nickel silicide (NiSi), copper, silver, gold, palladium, platinum, iron, cobalt, and aluminum.

A thickness of the first layer 222 and/or a thickness of the third layer 222 may be in a range from about 100 nm to about 5 μm.

In FIG. 2I, the first layer 222 and the third layer 222 are shown without any additional element that they may be attached to (except the second layer 101). Typically, however, each of the first layer 222 and/or the third layer 222 may be part of or fixed to an element or a device that is supposed to be connected by the second layer 101.

Exemplary embodiments of layer structures 200 that include such elements or devices are shown in FIG. 2A to FIG. 2H, FIG. 3A and FIG. 3B.

The layer structure 200 may, in various embodiments, include a plurality of first layers 222, a plurality of second layers 101, and a plurality of third layers 222.

In various embodiments, at least one of the first layer 222 and of the third layer 222 may be or include a chip metallization 220B, 220F, also referred to as contact surface. Chip metallizations 220B, 220F may be present on two opposite sides of the chip 220, referred to as backside metallization 220B and frontside metallization 220F, respectively. One or both of the chip metallizations 220F, 220B may include or consist of nickel and/or a nickel alloy, or a different metal, for example the particle metal, or, generally, copper, silver, gold, palladium, platinum, iron, cobalt, and/or aluminum. In various embodiments, the nickel and/or nickel alloy may be capped by a metal finish (e.g. Ni/Au, NiP/Pd/Au, etc.) to avoid oxidation. The metal finish may be configured in such a way, e.g. regarding thickness, composition, etc., that the soldering process as described herein, in particular the forming of the intermetallic phase, is undisturbed or essentially undisturbed.

A thickness of one or both of the chip metallizations 220F, 220B may at least 200 nm, e.g. in a range from about 200 nm to about 5 μm.

In the exemplary embodiment of FIG. 2A, a first interconnect may be formed by one of the first layers 222 formed on an electrically conductive substrate 224, e.g. on a leadframe, e.g. a copper leadframe, one of the second layers 101 connected to the first layer 222, and one of the third layers 222, which may be a backside metallization 220B of a chip 220, also referred to as a contact surface of the chip 220, i.e. a backside contact surface.

A second interconnect may be formed by another of the first layers 222, which may be a frontside metallization 220F of a chip 220, another of the second layers 101 connected to the first layer 222, and another of the third layers 222, which may be a plating layer 222 formed on an electrically conductive structure 226, e.g. on a clip, e.g. a copper clip, or the like.

The embodiment of FIG. 2B may differ from the embodiment of FIG. 2A essentially in that the second interconnect does not include the clip carrying the another of the third layers 222. Instead, a differently configured metal contact 226, e.g. a copper contact, may be provided on which the another of the third layers 222 is formed.

The embodiment of FIG. 2C may differ from the embodiments of FIG. 2A and FIG. 2B essentially in that the second interconnect is not formed. Instead, the frontside metallization 220F of the chip 220 may be exposed, for example for being contacted by conventional means, e.g. as described above, e.g. by a diffusion solder interconnect.

The embodiment of FIG. 2D may differ from the embodiment of FIG. 2B essentially in that the electrically conductive substrate 224 of FIG. 2D is replaced by an isolated substrate 224, 232, 234 including an electrically conductive layer 224, e.g. a copper layer, having the first layer 222 formed on its front side, a ceramics layer 232 attached with its front side to a backside of the electrically conductive layer 224, and a metal layer 234 attached to a backside of the ceramics layer 232.

The embodiment of FIG. 2E may differ from the embodiment of FIG. 2C essentially in that the electrically conductive substrate 224 of FIG. 2D is replaced by an isolated substrate 224, 232, 234 including an electrically conductive layer 224, e.g. a copper layer, having the first layer 222 formed on its front side, a ceramics layer 232 attached with its front side to a backside of the electrically conductive layer 224, and a metal layer 234 attached to a backside of the ceramics layer 232.

The embodiment of FIG. 2F may differ from the embodiment of FIG. 2E essentially in that the isolated substrate 224, 232, 234 is not provided, but instead a two-layered isolated substrate 224, 232 is provided. The two-layered isolated substrate 224, 232 may include an electrically conductive layer 224, e.g. a copper layer, having the first layer 222 formed on its front side, and an electrically insulating layer 232 attached with its front side to a backside of the electrically conductive layer 224. The electrically insulating layer 232 may include or consist of any electrically insulating material(s) used in the art for isolated substrates, e.g. ceramics, glass, an organic material, etc.

The embodiment of FIG. 2G may differ from the embodiment of FIG. 2D essentially in that the isolated substrate 224, 232, 234 is not provided, but instead a two-layered isolated substrate 224, 232 is provided. The two-layered isolated substrate 224, 232 may include an electrically conductive layer 224, e.g. a copper layer, having the first layer 222 formed on its front side, and an electrically insulating layer 232 attached with its front side to a backside of the electrically conductive layer 224. The electrically insulating layer 232 may include or consist of any electrically insulating material(s) used in the art for isolated substrates, e.g. ceramics, glass, an organic material, etc.

The embodiment of FIG. 2H may differ from the embodiment of FIG. 2B in that the first interconnect is not formed. Instead, the backside 220B of the chip 220 may be attached to the electrically conductive substrate 224 by diffusion soldering.

In various embodiments, the second layer 101 may consist of or essentially consist of the particle metal and the solder base metal.

The embodiments of layer structures 200 shown in FIG. 3A and FIG. 3B, respectively, may be similar or identical to the layer structure 200 of FIG. 2C, except for visualizing properties of the second layer 101.

The second layer 101 may include an intermetallic phase of the particle metal and the solder base metal.

In various embodiments, an exemplary embodiment of which is shown in FIG. 3A, the second layer 101 may consist of or essentially consist of the intermetallic phase. In this case, an absolute amount of the particle metal contained in the first amount of particles 104_1 and in the second amount of particles 104_2 of the solder material 100, and/or a relative amount of the particle metal contained in the first amount of particles 104_1 and in the second amount of particles 104_2, respectively, and/or an absolute and/or relative size of the first amount of particles 104_1 and the second amount of particles 104_2 may have been selected such that not only the first amount of particles 104_1 melted completely, but also the second amount of particles 104_2 essentially or completely melted to form the intermetallic phase.

In various embodiments, an exemplary embodiment of which is shown in FIG. 3B, the second layer 101 may include particles 104_2 having a size that is larger than a thickness of the first layer 222 and/or larger than a thickness of the third layer 222. The particles 104_2 may be remnants of the amount of second particles 104_2, i.e. of the larger particles 104_2, that were originally contained in the solder material 100, and may thus include or consist of the particle metal. During the soldering process, a fraction of the larger particles 104_2 may have melted when a temperature of the solder material 100 surrounding the larger particles 104_2 reached a melting temperature of the nickel. However, before melting the whole larger nickel particles 104_2, the melted solder material 100 reached a composition that was suitable for forming the intermetallic phase, and thus solidified, thereby enclosing what remained of the larger particles 104_2.

A similar situation may occur if particles having a size that is different from the size of the first amount of particles 104_1 and/or from the size of the second amount of particles 104_2, e.g. the third amount of particles 104_3 and/or the further particles 104_E. Particles up to a limiting size may have been completely melted and included in the intermetallic phase, whereas remnants of the particles larger than the limiting size may remain in the second layer 101. The limiting size may be higher than a maximum size of the first amount of particles 104_1 present in the solder material 100.

In other words, the second layer 101 may further include further particles having a size that is smaller than the size of the particles 104_2.

In various embodiments, the intermetallic phase may form between about 70% and about 95% (e.g., about 80%) by weight of the second layer 101.

The intermetallic phase may in various embodiments consists of or essentially consists of any of the following: an indium-copper intermetallic phase, for example Cu₁₁In₉ and/or Cu₂In, an indium-nickel intermetallic phase, for example In₇Ni₃ and/or In₃Ni₂, an indium-silver intermetallic phase, for example Ag₃In₂, and/or Ag₃In, and/or Ag₂In, an indium-gold intermetallic phase, for example AuIn, and/or Au₇In₃ and/or AuIn₂, an indium-palladium intermetallic phase, for example In₂Pd₅, and/or In₂Pd₄, and/or In₂Pd₆, an indium-platinum intermetallic phase, for example Pt₃In, a zinc-nickel intermetallic phase, for example NiZn-beta and/or NiZn-gamma, a zinc-silver intermetallic phase, for example AgZn-gamma and/or Ag₃Zn, a zinc-gold intermetallic phase, for example Au₃Zn, and/or Au₆Zn₃, and/or Au₄Zn₅, a zinc-palladium intermetallic phase, for example Pd₂Zn and/or PdZn₂, a zinc-platinum intermetallic phase, for example Pt₃Zn and/or PtZn, an antimony-copper intermetallic phase, for example Cu₂Sb, an antimony-silver intermetallic phase, for example SbAg₃, an antimony-gold intermetallic phase, for example AuSb₂, an antimony-palladium intermetallic phase, for example Pd₃Sb, an antimony-platinum intermetallic phase, for example Pt₅Sb, a bismuth-nickel intermetallic phase, for example BiNi and/or Bi₃Ni, a bismuth-gold intermetallic phase, for example Au₂Bi, a bismuth-palladium intermetallic phase, for example BiPd, and/or Bi₃Pd₅, and/or BiPd₃, and a bismuth-platinum intermetallic phase, for example BiPt and/or Bi₂Pt, an indium-nickel intermetallic phase, for example In₇Ni₃ and/or In₃Ni₂, a zinc-nickel intermetallic phase, for example NiZn-beta and/or NiZn-gamma, and a bismuth-nickel intermetallic phase, for example BiNi and/or Bi₃Ni.

The metals forming the intermetallic phase may contribute the following amounts (each in at %) as indicated in table 2:

TABLE 2

| Intermetallic | metal from particle, | metal from solder base, |
|---|---|---|
| phase | amount in at % | amount in at % |
| Cu₁₁In₉ | Cu, 55 | In, 45 |
| Cu₂In | Cu, 67 | In, 33 |
| In₇Ni₃ | Ni, 30 | In, 70 |
| In₃Ni₂ | Ni, 40 | In, 60 |
| Ag₃In₂ | Ag, 60 | In, 40 |
| Ag₃In | Ag, 75 | In, 25 |
| Ag₂In | Ag, 67 | In, 33 |
| AuIn | Au, 50 | In, 50 |
| Au₇In₃ | Au, 30 | In, 70 |
| AuIn₂ | Au, 22 | In, 67 |
| In₃Pd₅ | Pd, 63 | In, 37 |
| In₂Pd₄ | Pd, 67 | In, 33 |
| In₂Pd₆ | Pd, 75 | In, 25 |
| Pt₃In | Pt, 75 | In, 25 |
| NiZn-β | Ni, 56-48 | Zn, 44-52 |
| NiZn-γ | Ni, 26-15 | Zn, 74-85 |
| AgZn-γ | Ag, 39-24 | Zn, 61-76 |
| Ag₃Zn | Ag, 75 | Zn, 25 |
| Au₃Zn | Au, 75 | Zn, 25 |
| Au₆Zn₃ | Au, 77-73 | Zn, 23-27 |
| Au₄Zn₅ | Au, 48-33 | Zn, 52-57 |
| Pd₂Zn | Pd, 67 | Zn, 33 |
| PdZn₂ | Pd, 33 | Zn, 67 |
| Pt₃Zn | Pt, 75 | Zn, 25 |
| PtZn | Pt, 50 | Zn, 50 |
| Cu₂Sb | Cu, 67 | Sb, 33 |
| SbAg₃ | Ag, 25 | Sb, 75 |
| AuSb₂ | Au, 33 | Sb, 67 |
| Pd₃Sb | Pd, 75 | Sb, 25 |
| Pt₅Sb | Pt, 83 | Sb, 17 |
| BiNi | Ni, 52-50 | Bi, 52-50 |
| Bi₃Ni | Ni, 25 | Bi, 75 |
| Au₂Bi | Au, 67 | Bi, 33 |
| BiPd | Pd, 50 | Bi, 50 |
| Bi₃Pd₅ | Pd, 63-67 | Bi, 37-33 |
| BiPd₃ | Pd, 75 | Bi, 25 |
| BiPt | Pt, 50 | Bi, 50 |
| Bi₂Pt | Pt, 33 | Bi, 67 |

| | |
|---|---|
| BiAg | eutectic |

| | | |
|---|---|---|
| In₇Ni₃ | Ni, 70 | In, 30 |
| In₃Ni₂ | Ni, 40 | In, 60 |

A thickness of the second layer 101 may be in a range from about 50 μm to about 70 μm.

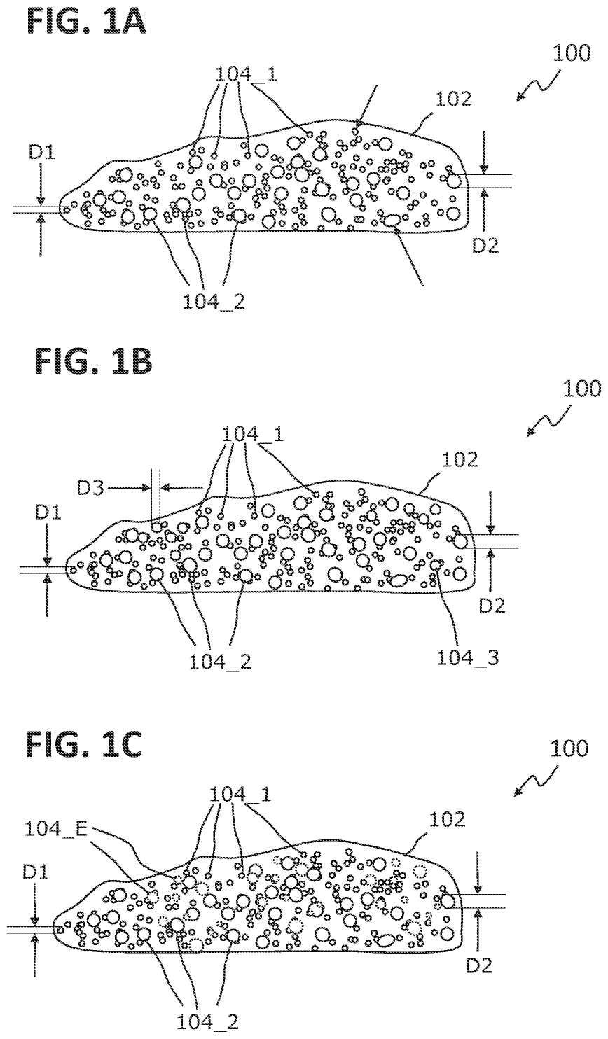

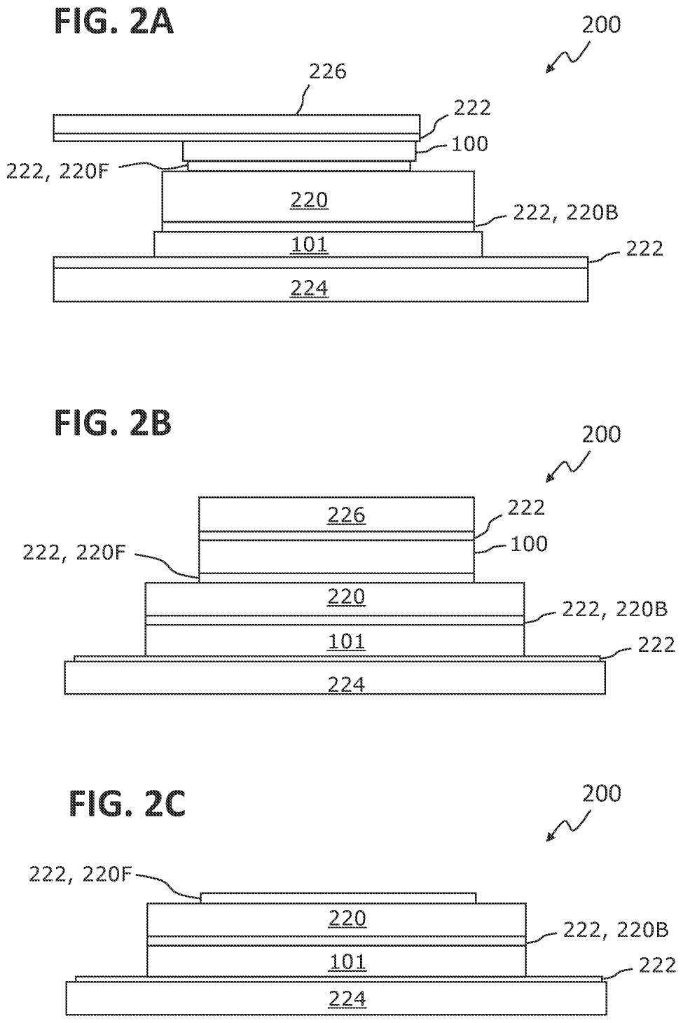

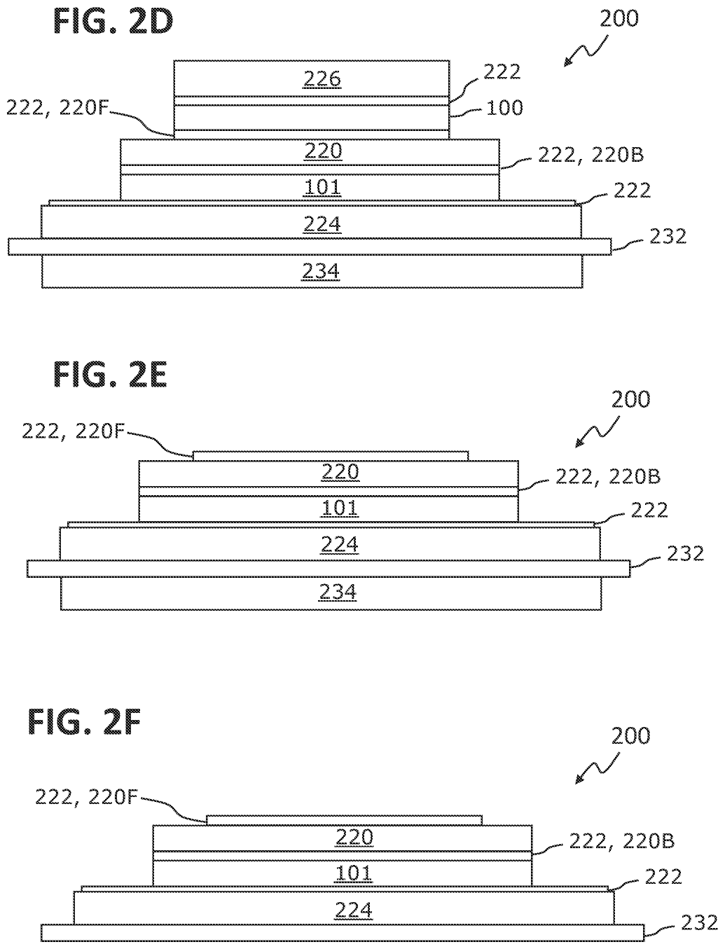

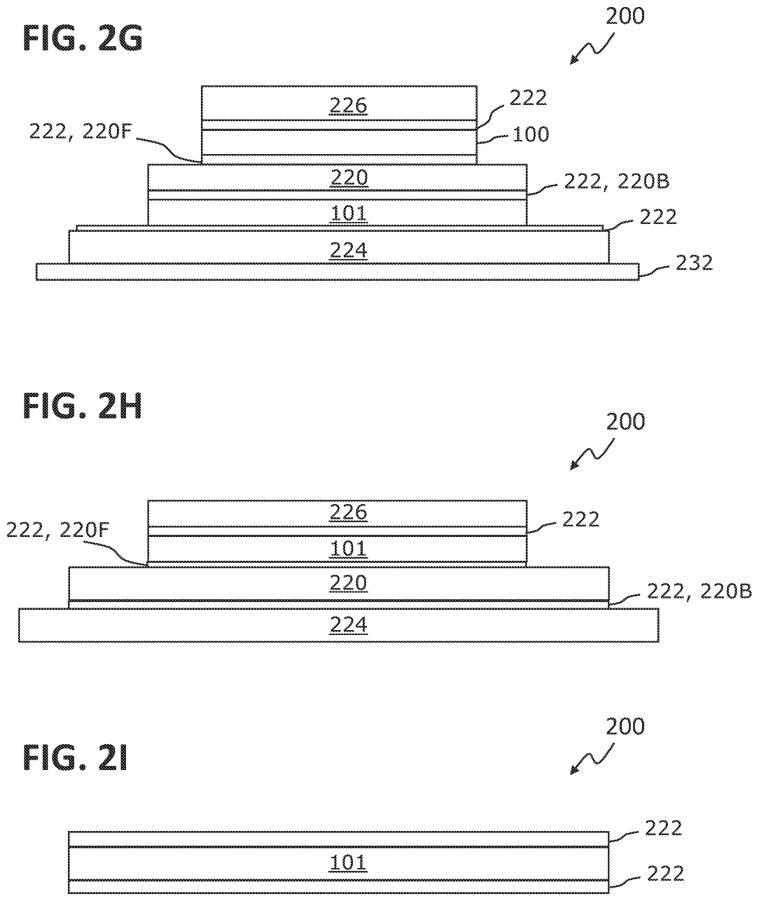

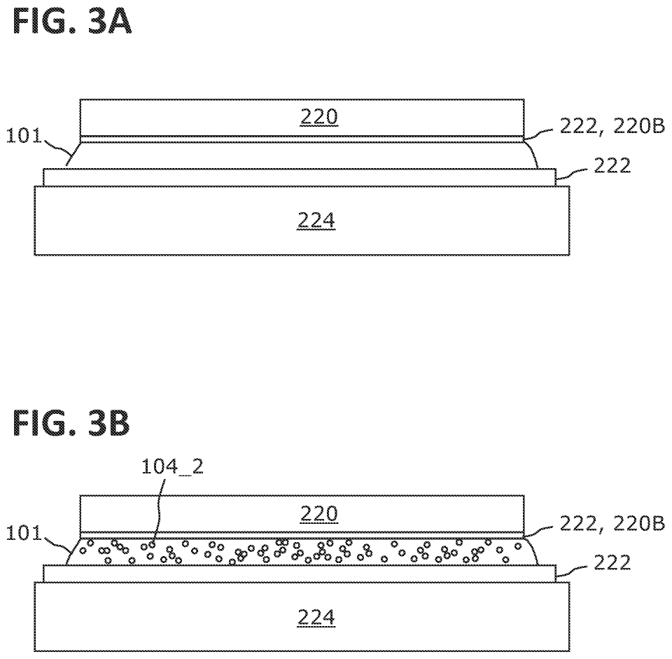

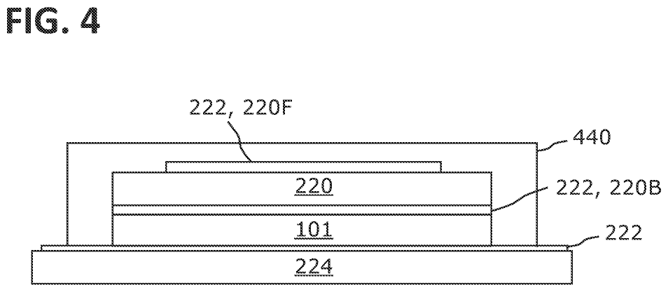

FIG. 4 shows a schematic cross-sectional view of a chip package 400 in accordance with various embodiments.

The chip package 400 may include a layer structure 200 as described above, for example as described in context with any of the embodiments of FIG. 2A to FIG. 2I, FIG. 3A and/or FIG. 3B. For illustrative purposes, the embodiment of FIG. 2C was selected as a basis for the chip package 400.

The chip package 400 may include a chip 220. The chip 220 is already included in the embodiments of layer structures 200 of FIG. 2A to FIG. 2H, FIG. 3A and FIG. 3B, but would need to be added to the embodiment of the layer structure 200 of FIG. 2I.

The chip 220 may include the first layer 222, e.g. as a (e.g., backside) chip metallization 220B, a conductive substrate 224, 222 including the third layer 222, and an encapsulation 440 at least partially encapsulating the chip 220 and at least one of the first layer 222, 220B, the second layer 100, and the third layer 222.

The encapsulation 440 may include or consist of an encapsulation material as known in the art, and may be arranged by known processes.

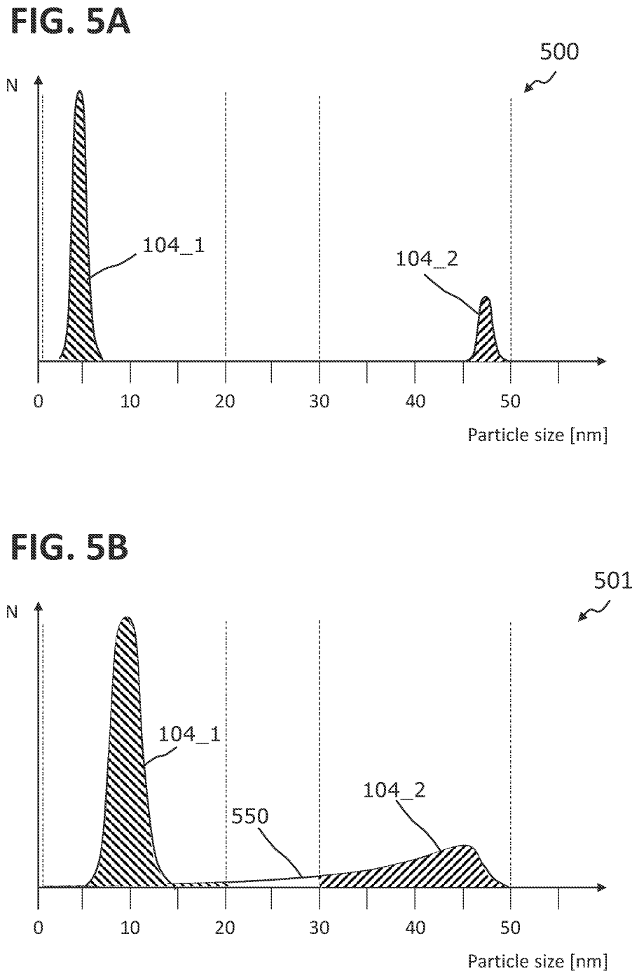

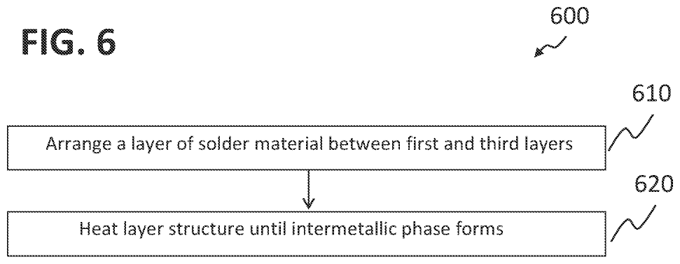

FIG. 6 shows a flow diagram 600 of a method of forming a layer structure in accordance with various embodiments.

The method may include arranging a layer of a solder material as described above in accordance with various embodiments between a first and a third layer (610).

Depending on the type of solder material that may be used, the arranging may be conducted differently, and essentially as known in the art, for example as known from solder materials containing lead.

For example, in a case of applying the solder material as a solder paste, the paste may be applied by dispensing or printing the paste onto the first layer and/or onto the second layer, e.g. onto the leadframe and/or onto the die frontside and/or onto the clip and/or onto the die backside. In a case of applying the solder material as a solder preform or other solid type of solder material, the solder preform etc. may be arranged over the first layer, and the second layer may be arranged over the solder material.

The method may further include heating the layer structure to a melting temperature of the solder material until an intermetallic phase forms (620).

In various embodiments, a plurality of solder interconnects may be formed simultaneously in the same layer structure, e.g. one over the other.

Alternatively, since a melting temperature of the intermetallic phase is much higher than a melting temperature of the solder material, sequential forming of solder interconnects in a device may be performed.

For example, after the arranging of the solder material between the first layer and the second layer, e.g. after placement of the chip on a leadframe and a clip on the die frontside (here, two solder connections may be formed simultaneously, one between the leadframe and the chip, and the other between the chip and the clip, which may lead to a layer structure as shown in FIG. 2A), thereby forming a stack, the stack may be heated in a reflow or box oven with a specific temperature profile adjusted to the mentioned materials and thicknesses. Alternatively, the two-step process with separate reflow processes for the die attach and for the clip attach may be performed.

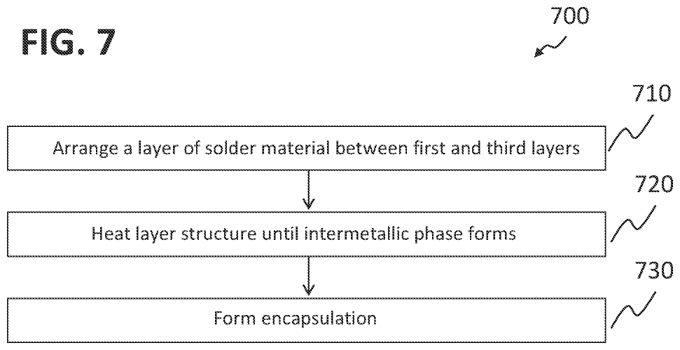

FIG. 7 shows a flow diagram 700 of a method of forming a chip package in accordance with various embodiments.

The method may include arranging a layer of a solder material as described above in accordance with various embodiments between a first layer and a third layer, wherein the first layer is a chip metallization layer, and wherein the second layer is part of a conductive substrate (710).

The method may further include heating the layer structure to a melting temperature of the solder material until an intermetallic phase forms (720).

Up to this point, the method of forming a chip package may be identical to the method of forming a layer structure in a case of the first layer being a chip metallization layer, and the second layer being part of a conductive substrate.

The method may further include forming an encapsulation at least partially encapsulating the chip and the layer structure (730).

Various examples will be illustrated in the following:

Example 1 is a solder material. The solder material may include a first amount of particles having particle sizes forming a first size distribution, a second amount of particles having particle sizes forming a second size distribution, wherein the particle sizes of the second size distribution are larger than the particle sizes of the first size distribution, and a solder base material in which the first amount of particles and the second amount of particles is distributed, wherein the first amount of particles and the second amount of particles consists of or essentially consists of a metal of a first group of metals, the first group including copper, silver, gold, palladium, platinum, iron, cobalt, and aluminum, and wherein the solder base material includes a metal of a second group of metals, the second group including tin, indium, zinc, gallium, germanium, antimony, and bismuth.

Example 2 is a solder material. The solder material may include a first amount of particles having particle sizes forming a first size distribution, a second amount of particles having particle sizes forming a second size distribution that is separated from the first size distribution, wherein the particle sizes of the second size distribution are larger than the particle sizes of the first size distribution, and a solder base material in which the first amount of particles and the second amount of particles is distributed, wherein the first amount of particles and the second amount of particles consists of or essentially consists of a metal of a first group of metals, the first group including nickel, copper, silver, gold, palladium, platinum, iron, cobalt, and aluminum, and wherein the solder base material includes a metal of a second group of metals, the second group including indium, zinc, gallium, germanium, antimony, and bismuth.

In Example 3, the subject matter of Example 1 or 2 may additionally include that a median particle size of the second size distribution is at least twice as large as a median particle size of the first size distribution.

Example 4 is a solder material. The solder material may include a first amount of particles having a size in a range from about 1 μm to about 20 μm, a second amount of particles having a size in a range from about 30 μm to about 50 μm, and a solder base material in which the first amount of particles and the second amount of particles is distributed, wherein the first amount of particles and the second amount of particles consists of or essentially consists of a metal of a first group of metals, the first group including copper, silver, gold, palladium, platinum, iron, cobalt, and aluminum, and wherein the solder base material includes a metal of a second group of metals, the second group including tin, indium, zinc, gallium, germanium, antimony, and bismuth.

Example 5 is a solder material. The solder material may include a first amount of particles having a size in a range from about 1 μm to about 20 μm, a second amount of particles having a size in a range from about 30 μm to about 50 μm, and a solder base material in which the first amount of particles and the second amount of particles is distributed, wherein the first amount of particles and the second amount of particles consists of or essentially consists of a metal of a first group of metals, the first group including nickel, copper, silver, gold, palladium, platinum, iron, cobalt, and aluminum, and wherein the solder base material includes a metal of a second group of metals, the second group including indium, zinc, gallium, germanium, antimony, and bismuth.

In Example 6, the subject matter of any of Examples 1 to 5 may additionally include that a sum of the first amount of particles and the second amount of particles is a total amount of the first metal or less.

In Example 7, the subject matter of any of Examples 1 to 6 may additionally include that the first amount of particles is between 5 at % and 60 at %, optionally between 25 at % and 60 at %, of the total amount of the first metal.

In Example 8, the subject matter of any of Examples 1 to 7 may additionally include that the second amount of particles is between 10 at % and 95 at %, optionally between 10 at % and 75 at %, of the total amount of the first metal.

In Example 9, the subject matter of any of Examples 1 to 8 may additionally include that the particles are spherical or essentially spherical.

In Example 10, the subject matter of any of Examples 1 to 9 may additionally include a third amount of particles consisting of or essentially consisting of the first metal, wherein the particles of the third amount of particles have a size in a range from more than 20 μm to less than 30 μm, and wherein, optionally, the third amount of particles is between 10 at % and 85 at % of the total amount of the first metal.

In Example 11, the subject matter of any of Examples 1 to 10 may additionally include that the first metal amounts to about 35 at % to about 90 at % of the solder material.

In Example 12, the subject matter of any of Examples 1 to 11 may additionally include that the solder material is configured as a solder paste, a solder wire, a compacted solder powder, or as a solder preform.

Example 13 is a layer structure. The layer structure may include a first layer, a third layer, and a second layer attaching the first layer to the third layer, wherein the second layer consists of or essentially consists of a first metal and a second metal, wherein the second layer includes an intermetallic phase of the first metal and the second metal, and wherein the first metal is a metal of a first group of metals, the first group including copper, silver, gold, palladium, platinum, iron, cobalt, and aluminum, and wherein the second metal is a metal of a second group of metals, the second group including tin, indium, zinc, gallium, germanium, antimony, and bismuth.

Example 14 is a layer structure. The layer structure may include a first layer, a third layer, and a second layer attaching the first layer to the third layer, wherein the second layer consists of or essentially consists of a first metal and a second metal, wherein the second layer includes an intermetallic phase of the first metal and the second metal, and wherein the first metal is a metal of a first group of metals, the first group including nickel, copper, silver, gold, palladium, platinum, iron, cobalt, and aluminum, and wherein the second metal is a metal of a second group of metals, the second group including indium, zinc, gallium, germanium, antimony, and bismuth.

In Example 15, the subject matter of any of Examples 13 or 14 may additionally include that the second layer includes particles of the first metal having a size that is larger than a thickness of the first layer and/or larger than a thickness of the third layer.

In Example 16, the subject matter of any of Examples 13 to 15 may additionally include that the intermetallic phase forms between about 70% and about 95% by weight of the second layer.

In Example 17, the subject matter of any of Examples 13 to 16 may additionally include that the first layer and/or the third layer includes or consists of a metal, wherein the metal is optionally the same as the first metal.

In Example 18, the subject matter of any of Examples 13 and 15 to 17 may additionally include that the intermetallic phase consists of or essentially consists of one of a group of intermetallic phases, the group including a tin-copper intermetallic phase, for example Cu₆Sn₅ and/or Cu₃Sn, a tin-silver intermetallic phase, for example Ag₃Sn, a tin-gold intermetallic phase, for example AuSn and/or Au₅Sn, a tin-palladium intermetallic phase, for example PdSn₄, and/or PdSn₃, and/or PdSn₂, an indium-copper intermetallic phase, for example Cu₁₁In₉ and/or Cu₂In, an indium-silver intermetallic phase, for example Ag₃In₂, and/or Ag₃In, and/or Ag₂In, an indium-gold intermetallic phase, for example AuIn, and/or Au₇In₃ and/or AuIn₂, an indium-palladium intermetallic phase, for example In₂Pd₅, and/or In₂Pd₄, and/or In₂Pd₆, an indium-platinum intermetallic phase, for example Pt₃In, a zinc-silver intermetallic phase, for example AgZn-gamma and/or Ag₃Zn, a zinc-gold intermetallic phase, for example Au₃Zn, and/or Au₆Zn₃, and/or Au₄Zn₅, a zinc-palladium intermetallic phase, for example Pd₂Zn and/or PdZn₂, a zinc-platinum intermetallic phase, for example Pt₃Zn and/or PtZn, an antimony-copper intermetallic phase, for example Cu₂Sb, an antimony-silver intermetallic phase, for example SbAg₃, an antimony-gold intermetallic phase, for example AuSb₂, an antimony-palladium intermetallic phase, for example Pd₃Sb, an antimony-platinum intermetallic phase, for example Pt₅Sb, a bismuth-gold intermetallic phase, for example Au₂Bi, a bismuth-palladium intermetallic phase, for example BiPd, and/or Bi₃Pd₅, and/or BiPd₃, and a bismuth-platinum intermetallic phase, for example BiPt and/or Bi₂Pt.

In Example 19, the subject matter of any of Examples 14 to 17 may additionally include that the intermetallic phase consists of or essentially consists of one of a group of intermetallic phases, the group including an indium-copper intermetallic phase, for example Cu₁₁In₉ and/or Cu₂In, an indium-nickel intermetallic phase, for example In₇Ni₃ and/or In₃Ni₂, an indium-silver intermetallic phase, for example Ag₃In₂, and/or Ag₃In, and/or Ag₂In, an indium-gold intermetallic phase, for example AuIn, and/or Au₇In₃ and/or AuIn₂, an indium-palladium intermetallic phase, for example In₂Pd₅, and/or In₂Pd₄, and/or In₂Pd₆, an indium-platinum intermetallic phase, for example Pt₃In, a zinc-nickel intermetallic phase, for example NiZn-beta and/or NiZn-gamma, a zinc-silver intermetallic phase, for example AgZn-gamma and/or Ag₃Zn, a zinc-gold intermetallic phase, for example Au₃Zn, and/or Au₆Zn₃, and/or Au₄Zn₅, a zinc-palladium intermetallic phase, for example Pd₂Zn and/or PdZn₂, a zinc-platinum intermetallic phase, for example Pt₃Zn and/or PtZn, an antimony-copper intermetallic phase, for example Cu₂Sb, an antimony-silver intermetallic phase, for example SbAg₃, an antimony-gold intermetallic phase, for example AuSb₂, an antimony-palladium intermetallic phase, for example Pd₃Sb, an antimony-platinum intermetallic phase, for example Pt₅Sb, a bismuth-nickel intermetallic phase, for example BiNi and/or Bi₃Ni, a bismuth-gold intermetallic phase, for example Au₂Bi, a bismuth-palladium intermetallic phase, for example BiPd, and/or Bi₃Pd₅, and/or BiPd₃, and a bismuth-platinum intermetallic phase, for example BiPt and/or Bi₂Pt.

In Example 20, the subject matter of any of Examples 13 to 19 may additionally include that the first layer and/or the third layer includes, consists of, or essentially consists of at least one of a group including nickel, nickel vanadium (NiV), a nickel phosphide, e.g. NiP, and nickel silicide (NiSi), copper, silver, gold, palladium, platinum, iron, cobalt, and aluminum.

In Example 21, the subject matter of any of Examples 13 to 20 may additionally include that a thickness of the first layer and/or a thickness of the third layer is in a range from about 100 nm to about 5 μm.

In Example 22, the subject matter of any of Examples 13 to 21 may additionally include that a thickness of the second layer is in a range from about 50 μm to about 70 μm.

Example 23 is a chip package. The chip package may include the layer structure of any of Example 13 to 22, a chip including the first layer, a conductive substrate including the third layer, and an encapsulation at least partially encapsulating the chip and at least one of the first layer, the second layer, and the third layer.

Example 24 is a method of forming a layer structure. The method may include arranging a layer of a solder material in accordance with any of Examples 1 to 12 between a first layer and a third layer, and heating the layer structure to a melting temperature of the solder material until an intermetallic phase forms.

In Example 25, the subject matter of Example 24 may additionally include that the first layer and/or of the third layer includes or consists of a metal, wherein the metal is optionally the same as the first metal of the solder material.

In Example 26, the subject matter of Example 24 or 25 may additionally include that the second layer includes particles of the first metal having a size that is larger than a thickness of the first layer and/or larger than a thickness of the third layer.

In Example 27, the subject matter of any of Examples 24 to 26 may additionally include that the intermetallic phase forms between about 80% and about 95% by weight of the second layer.

In Example 28, the subject matter of any of Examples 24, 26 or 27 may additionally include that the intermetallic phase consists of or essentially consists of one of a group of intermetallic phases, the group including a tin-copper intermetallic phase, for example Cu₆Sn₅ and/or Cu₃Sn, a tin-silver intermetallic phase, for example Ag₃Sn, a tin-gold intermetallic phase, for example AuSn and/or Au₅Sn, a tin-palladium intermetallic phase, for example PdSn₄, and/or PdSn₃, and/or PdSn₂, an indium-copper intermetallic phase, for example Cu₁₁In₉ and/or Cu₂In, an indium-silver intermetallic phase, for example Ag₃In₂, and/or Ag₃In, and/or Ag₂In, an indium-gold intermetallic phase, for example AuIn, and/or Au₇In₃ and/or AuIn₂, an indium-palladium intermetallic phase, for example In₂Pd₅, and/or In₂Pd₄, and/or In₂Pd₆, an indium-platinum intermetallic phase, for example Pt₃In, a zinc-silver intermetallic phase, for example AgZn-gamma and/or Ag₃Zn, a zinc-gold intermetallic phase, for example Au₃Zn, and/or Au₆Zn₃, and/or Au₄Zn₅, a zinc-palladium intermetallic phase, for example Pd₂Zn and/or PdZn₂, a zinc-platinum intermetallic phase, for example Pt₃Zn and/or PtZn, an antimony-copper intermetallic phase, for example Cu₂Sb, an antimony-silver intermetallic phase, for example SbAg₃, an antimony-gold intermetallic phase, for example AuSb₂, an antimony-palladium intermetallic phase, for example Pd₃Sb, an antimony-platinum intermetallic phase, for example Pt₅Sb, a bismuth-gold intermetallic phase, for example Au₂Bi, a bismuth-palladium intermetallic phase, for example BiPd, and/or Bi₃Pd₅, and/or BiPd₃, and a bismuth-platinum intermetallic phase, for example BiPt and/or Bi₂Pt.

In Example 29, the subject matter of any of Examples 25 to 27 may additionally include that the intermetallic phase consists of or essentially consists of one of a group of intermetallic phases, the group including an indium-copper intermetallic phase, for example Cu₁₁In₉ and/or Cu₂In, an indium-nickel intermetallic phase, for example In₇Ni₃ and/or In₃Ni₂, an indium-silver intermetallic phase, for example Ag₃In₂, and/or Ag₃In, and/or Ag₂In, an indium-gold intermetallic phase, for example AuIn, and/or Au₇In₃ and/or AuIn₂, an indium-palladium intermetallic phase, for example In₂Pd₅, and/or In₂Pd₄, and/or In₂Pd₆, an indium-platinum intermetallic phase, for example Pt₃In, a zinc-nickel intermetallic phase, for example NiZn-beta and/or NiZn-gamma, a zinc-silver intermetallic phase, for example AgZn-gamma and/or Ag₃Zn, a zinc-gold intermetallic phase, for example Au₃Zn, and/or Au₆Zn₃, and/or Au₄Zn₅, a zinc-palladium intermetallic phase, for example Pd₂Zn and/or PdZn₂, a zinc-platinum intermetallic phase, for example Pt₃Zn and/or PtZn, an antimony-copper intermetallic phase, for example Cu₂Sb, an antimony-silver intermetallic phase, for example SbAg₃, an antimony-gold intermetallic phase, for example AuSb₂, an antimony-palladium intermetallic phase, for example Pd₃Sb, an antimony-platinum intermetallic phase, for example Pt₅Sb, a bismuth-nickel intermetallic phase, for example BiNi and/or Bi₃Ni, a bismuth-gold intermetallic phase, for example Au₂Bi, a bismuth-palladium intermetallic phase, for example BiPd, and/or Bi₃Pd₅, and/or BiPd₃, and a bismuth-platinum intermetallic phase, for example BiPt and/or Bi₂Pt.

In Example 30, the subject matter of any of Examples 24 to 29 may additionally include that the second layer further includes further particles of the first metal having a size that is smaller than the size of the nickel particles.

In Example 31, the subject matter of any of Examples 24 to 30 may additionally include that the first layer and/or the second layer includes, consists of, or essentially consists of at least one of a group including nickel, nickel vanadium (NiV), a nickel phosphide, e.g. NiP, and nickel silicide (NiSi), copper, silver, gold, palladium, platinum, iron, cobalt, and aluminum.

In Example 32, the subject matter of any of Examples 24 to 31 may additionally include that a thickness of the first layer and/or a thickness of the third layer is in a range from about 100 nm to about 5 μm.

In Example 33, the subject matter of any of Examples 24 to 32 may additionally include that a thickness of the second layer is in a range from about 50 μm to about 70 μm.

Example 34 is a method of forming a chip package. The method may include forming the layer structure in accordance with any of Examples 24 to 33, wherein the first layer is a chip metallization layer, and wherein the second layer is part of a conductive substrate, and forming an encapsulation at least partially encapsulating the chip and the layer structure.

In Example 35, the subject matter of Examples 1 or 2 may additionally include that the first size distribution is separated from the second size distribution.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A solder material, comprising:
a first amount of particles having particle sizes forming a first size distribution;
a second amount of particles having particle sizes forming a second size distribution, wherein the particle sizes of the second size distribution are larger than the particle sizes of the first size distribution; and
a solder base material in which the first amount of particles and the second amount of particles are distributed,
wherein the first amount of particles and the second amount of particles consist of or essentially consist of a metal of a first group of metals, the first group of metals comprising:
copper;
silver;
gold;
palladium;
platinum;
iron;
cobalt; and
aluminum,
wherein the solder base material comprises a metal of a second group of metals, the second group of metals comprising:
tin;
indium;
zinc;
gallium;
germanium;
antimony; and
bismuth.

2. The solder material of claim 1, wherein a median particle size of the second size distribution is at least twice as large as a median size of the first particle size distribution.

3. The solder material of claim 1, wherein the first size distribution is separated from the second size distribution.

4. The solder material of claim 1, wherein a sum of the first amount of particles and the second amount of particles is a total amount of the first metal or less.

5. The solder material of claim 1, wherein the first amount of particles is between 5 at % and 60 at % of the total amount of the first metal.

6. The solder material of claim 1, wherein the second amount of particles is between 10 at % and 95 at % of the total amount of the first metal.

7. The solder material of claim 1, wherein the first metal amounts to about 35 at % to about 90 at % of the solder material.

8. The solder material of claim 1, wherein the solder material is configured as a solder paste, a solder wire, a compacted solder powder, or as a solder preform.

9. A solder material, comprising:
a first amount of particles having a size in a range from about 1 μm to about 20 μm;
a second amount of particles having a size in a range from about 30 μm to about 50 μm; and
a solder base material in which the first amount of particles and the second amount of particles are distributed,
wherein the first amount of particles and the second amount of particles consist of or essentially consist of a metal of a first group of metals, the first group of metals comprising:
copper;
silver;
gold;
palladium;
platinum;
iron;
cobalt; and
aluminum,
wherein the solder base material comprises a metal of a second group of metals, the second group of metals comprising:
tin;
indium;
zinc;
gallium;
germanium;
antimony; and
bismuth.

10. The solder material of claim 9, wherein a sum of the first amount of particles and the second amount of particles is a total amount of the first metal or less.

11. The solder material of claim 9, wherein the first amount of particles is between 5 at % and 60 at % of the total amount of the first metal.

12. The solder material of claim 9, wherein the second amount of particles is between 10 at % and 95 at % of the total amount of the first metal.

13. The solder material of claim 9, wherein the first metal amounts to about 35 at % to about 90 at % of the solder material.

14. The solder material of claim 9, wherein the solder material is configured as a solder paste, a solder wire, a compacted solder powder, or as a solder preform.

15. A solder material, comprising:
a first amount of particles having a size in a range from about 1 μm to about 20 μm;
a second amount of particles having a size in a range from about 30 μm to about 50 μm; and
a solder base material in which the first amount of particles and the second amount of particles are distributed,
wherein the first amount of particles and the second amount of particles consist of or essentially consist of a metal of a first group of metals, the first group of metals comprising:
nickel;
copper;
silver;
gold;
palladium;
platinum;
iron;
cobalt; and
aluminum,
wherein the solder base material comprises a metal of a second group of metals, the second group of metals comprising:
indium;
zinc;
gallium;
germanium;
antimony; and
bismuth.

16. The solder material of claim 15, wherein a sum of the first amount of particles and the second amount of particles is a total amount of the first metal or less.

17. The solder material of claim 15, wherein the first amount of particles is between 5 at % and 60 at % of the total amount of the first metal.

18. The solder material of claim 15, wherein the second amount of particles is between 10 at % and 95 at % of the total amount of the first metal.

19. The solder material of claim 15, wherein the first metal amounts to about 35 at % to about 90 at % of the solder material.

20. The solder material of claim 15, wherein the solder material is configured as a solder paste, a solder wire, a compacted solder powder, or as a solder preform.

21. A layer structure, comprising:
a first layer;
a third layer; and
a second layer attaching the first layer to the third layer,
wherein the second layer consists of or essentially consists of a first metal and a second metal,
wherein the second layer comprises an intermetallic phase of the first metal and the second metal,
wherein the first metal is a metal of a first group of metals, the first group of metals comprising:
copper;
silver;
gold;
palladium;
platinum;
iron;
cobalt; and
aluminum,
wherein the second metal is a metal of a second group of metals, the second group of metals comprising:
tin;
indium;
zinc;
gallium;
germanium;
antimony; and
bismuth.

22. The layer structure of claim 21, wherein the second layer comprises particles of the first metal having a size that is larger than a thickness of the first layer and/or larger than a thickness of the third layer.

23. The layer structure of claim 21, wherein the intermetallic phase forms between about 70% and about 95% by weight of the second layer.

24. The layer structure of claim 21, wherein the first layer and/or the third layer comprises or consists of a metal.

25. The layer structure of claim 21, wherein the intermetallic phase consists of or essentially consists of one of a group of intermetallic phases, the group of intermetallic phases comprising:
a tin-copper intermetallic phase;
a tin-silver intermetallic phase;
a tin-gold intermetallic phase;
a tin-palladium intermetallic phase;
an indium-copper intermetallic phase;
an indium-silver intermetallic phase;
an indium-gold intermetallic phase;
an indium-palladium intermetallic phase;
an indium-platinum intermetallic phase;
a zinc-silver intermetallic phase;
a zinc-gold intermetallic phase;
a zinc-palladium intermetallic phase;
a zinc-platinum intermetallic phase;
an antimony-copper intermetallic phase;
an antimony-silver intermetallic phase;
an antimony-gold intermetallic phase;
an antimony-palladium intermetallic phase;
an antimony-platinum intermetallic phase;
a bismuth-gold intermetallic phase;
a bismuth-palladium intermetallic phase; and
a bismuth-platinum intermetallic phase.

26. The layer structure of claim 21, wherein the first layer and/or the third layer comprises, consists of, or essentially consists of at least one of a group comprising:
nickel;
nickel vanadium;
a nickel phosphide; and
nickel silicide;
copper;
silver;
gold;
palladium;
platinum;
iron;
cobalt; and
aluminum.

27. The layer structure of claim 21, wherein a thickness of the first layer and/or a thickness of the third layer is in a range from about 100 nm to about 5μm, and/or wherein a thickness of the second layer is in a range from about 50 μm to about 70 μm.

28. A layer structure, comprising:
a first layer;
a third layer; and
a second layer attaching the first layer to the third layer,
wherein the second layer consists of or essentially consists of a first metal and a second metal,
wherein the second layer comprises an intermetallic phase of the first metal and the second metal,
wherein the first metal is a metal of a first group of metals, the first group of metals comprising:
nickel;
copper;
silver;
gold;
palladium;
platinum;
iron;
cobalt; and
aluminum,
wherein the second metal is a metal of a second group of metals, the second group of metals comprising:
indium;
zinc;
gallium;
germanium;
antimony; and
bismuth.

29. The layer structure of claim 28, wherein the second layer comprises particles of the first metal having a size that is larger than a thickness of the first layer and/or larger than a thickness of the third layer.

30. The layer structure of claim 28, wherein the intermetallic phase forms between about 70% and about 95% by weight of the second layer.

31. The layer structure of claim 28, wherein the first layer and/or the third layer comprises or consists of a metal.

32. The layer structure of claim 28, wherein the intermetallic phase consists of or essentially consists of one of a group of intermetallic phases, the group of intermetallic phases comprising:
an indium-copper intermetallic phase;
an indium-nickel intermetallic phase;
an indium-silver intermetallic phase;
an indium-gold intermetallic phase;
an indium-palladium intermetallic phase;
an indium-platinum intermetallic phase;
a zinc-nickel intermetallic phase;
a zinc-silver intermetallic phase;
a zinc-gold intermetallic phase;
a zinc-palladium intermetallic phase;
a zinc-platinum intermetallic phase;
an antimony-copper intermetallic phase;
an antimony-silver intermetallic phase;
an antimony-gold intermetallic phase;
an antimony-palladium intermetallic phase;
an antimony-platinum intermetallic phase;
a bismuth-nickel intermetallic phase;
a bismuth-gold intermetallic phase;
a bismuth-palladium intermetallic phase; and
a bismuth-platinum intermetallic phase.

33. The layer structure of claim 28, wherein the first layer and/or the third layer comprises, consists of, or essentially consists of at least one of a group comprising:
nickel;
nickel vanadium;
a nickel phosphide; and
nickel silicide;
copper;
silver;
gold;
palladium;
platinum;
iron;
cobalt; and
aluminum.

34. The layer structure of claim 28, wherein a thickness of the first layer and/or a thickness of the third layer is in a range from about 100 nm to about 5 μm, and/or wherein a thickness of the second layer is in a range from about 50 μm to about 70 μm.

35. A chip package, comprising:
the layer structure of claim 21 or claim 28;
a chip comprising the first layer;
a conductive substrate comprising the third layer; and
an encapsulation at least partially encapsulating the chip and at least one of the first layer, the second layer, and the third layer.

36. A method of forming a layer structure, the method comprising:
arranging a layer of the solder material of claim 1, claim 9, or claim 15 between a first layer and a third layer; and
heating the layer structure to a melting temperature of the solder material until an intermetallic phase forms.

37. The method of claim 36, wherein the first layer and/or of the third layer comprises or consists of a metal.

38. The method of claim 36, wherein the intermetallic phase forms between about 80% and about 95% by weight of the second layer.

39. The method of claim 36, wherein the intermetallic phase consists of or essentially consists of one of a group of intermetallic phases, the group of intermetallic phases comprising:
a tin-copper intermetallic phase;
a tin-silver intermetallic phase;
a tin-gold intermetallic phase;
a tin-palladium intermetallic phase;
an indium-copper intermetallic phase;
an indium-silver intermetallic phase;
an indium-gold intermetallic phase;
an indium-palladium intermetallic phase;
an indium-platinum intermetallic phase;
a zinc-silver intermetallic phase;
a zinc-gold intermetallic phase;
a zinc-palladium intermetallic phase;
a zinc-platinum intermetallic phase;
an antimony-copper intermetallic phase;
an antimony-silver intermetallic phase;
an antimony-gold intermetallic phase;
an antimony-palladium intermetallic phase;
an antimony-platinum intermetallic phase;
a bismuth-gold intermetallic phase;
a bismuth-palladium intermetallic phase; and
a bismuth-platinum intermetallic phase.

40. The method of claim 36, wherein the intermetallic phase consists of or essentially consists of one of a group of intermetallic phases, the group of intermetallic phases comprising:
an indium-copper intermetallic phase;
an indium-nickel intermetallic phase;
an indium-silver intermetallic phase;
an indium-gold intermetallic phase;
an indium-palladium intermetallic phase;
an indium-platinum intermetallic phase;
a zinc-nickel intermetallic phase;
a zinc-silver intermetallic phase;
a zinc-gold intermetallic phase;
a zinc-palladium intermetallic phase;
a zinc-platinum intermetallic phase;
an antimony-copper intermetallic phase;
an antimony-silver intermetallic phase;
an antimony-gold intermetallic phase;
an antimony-palladium intermetallic phase;
an antimony-platinum intermetallic phase;
a bismuth-nickel intermetallic phase;
a bismuth-gold intermetallic phase;
a bismuth-palladium intermetallic phase; and
a bismuth-platinum intermetallic phase.

41. A method of forming a chip package, the method comprising:
forming the layer structure of claim 21 or claim 28, wherein the first layer is a chip metallization layer of a chip, and wherein the second layer is part of a conductive substrate; and
forming an encapsulation at least partially encapsulating the chip and the layer structure.
